(19) United States
(12) Patent Application Publication
(10) Pub. No.: US 2025/0212417 A1
(43) Pub. Date: Jun. 26, 2025

(54) SEMICONDUCTOR STRUCTURE INCLUDING CRACK DETECTOR AND MANUFACTURING METHOD THEREOF

(71) Applicant: TAIWAN SEMICONDUCTOR MANUFACTURING COMPANY LTD., HSINCHU (TW)

(72) Inventors: YU-CHUAN SHIH, HSINCHU CITY (TW); CHUN-CHIEH LU, TAIPEI CITY (TW); KUO-CHANG CHIANG, HSINCHU CITY (TW); CHIH-YU CHANG, NEW TAIPEI CITY (TW); HUAI-YING HUANG, NEW TAIPEI CITY (TW); YU-MING LIN, HSINCHU CITY (TW)

(21) Appl. No.: 18/395,735

(22) Filed: Dec. 25, 2023

(51) Int. Cl. H10B 51/30; H10B 51/20; H10B 51/40

(52) U.S. Cl. CPC H10B 51/30; H10B 51/20; H10B 51/40

(57) ABSTRACT

A semiconductor structure includes a gate layer, a ferroelectric layer, a source structure, a drain structure, an oxide semiconductor and a high-k material layer. The gate layer is disposed in an interconnect structure. The ferroelectric layer is disposed over the gate layer. The source structure and the drain structure are disposed over the ferroelectric layer. The oxide semiconductor is disposed over the ferroelectric layer and between the source structure and the drain structure. The high-k material layer is disposed on and contacts a surface of the ferroelectric layer. A method of manufacturing the semiconductor structure is also provided.

### BACKGROUND

As the semiconductor industry has progressed into nanometer technology process nodes in pursuit of greater device density, higher performance, and lower costs, there is a need to incorporate and merge logic circuits having a variety of functions with non-volatile memory circuits within a single chip. Being a non-volatile memory cell, a ferroelectric random-access memory (FeRAM) offers high density, low power consumption, high speed, and low manufacturing cost. One advantage of the FeRAM compared to a static random-access memory (SRAM) or a dynamic random-access memory (DRAM) is the FeRAM's significantly smaller size. However, challenges in poor durability of the FeRAM have arisen.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIGS. 1 to 6 are schematic cross-sectional diagrams of semiconductor structures in accordance with different embodiments of the present disclosure.

FIG. 7 is a schematic cross-sectional diagram of a semiconductor structure in accordance with some embodiments of the present disclosure.

FIG. 8 is a schematic cross-sectional diagram of a memory unit of the semiconductor structure shown in FIG. 7 in accordance with some embodiments of the present disclosure.

FIG. 9 is a schematic cross-sectional diagram of a semiconductor structure in accordance with some embodiments of the present disclosure.

FIG. 10 is a 3D diagram of a semiconductor structure in accordance with some embodiments of the present disclosure.

FIG. 11 is a 3D diagram of a portion of the semiconductor structure shown in FIG. 10 cut along a line A-A′ in accordance with some embodiments of the present disclosure.

FIG. 12 is a cross-sectional diagram of the semiconductor structure shown in FIG. 10 along a line B-B′ in accordance with some embodiments of the present disclosure.

FIGS. 13 to 21 are schematic 3D diagrams at different stages of a manufacturing method of a semiconductor structure in accordance with some embodiments of the present disclosure.

FIG. 22 is a 3D diagram of a semiconductor structure in accordance with some embodiments of the present disclosure.

FIG. 23 is a 3D diagram of a semiconductor structure in accordance with some embodiments of the present disclosure.

FIG. 24 is a schematic top-view perspective showing electrical connections of the semiconductor structure shown in FIG. 23 in accordance with some embodiments of the present disclosure.

FIG. 25 is a flow diagram of a method for manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, the term “source/drain region” or “source/drain regions” may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from normal deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages, such as those for quantities of materials, durations of time, temperatures, operating conditions, ratios of amounts, and the likes thereof disclosed herein, should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

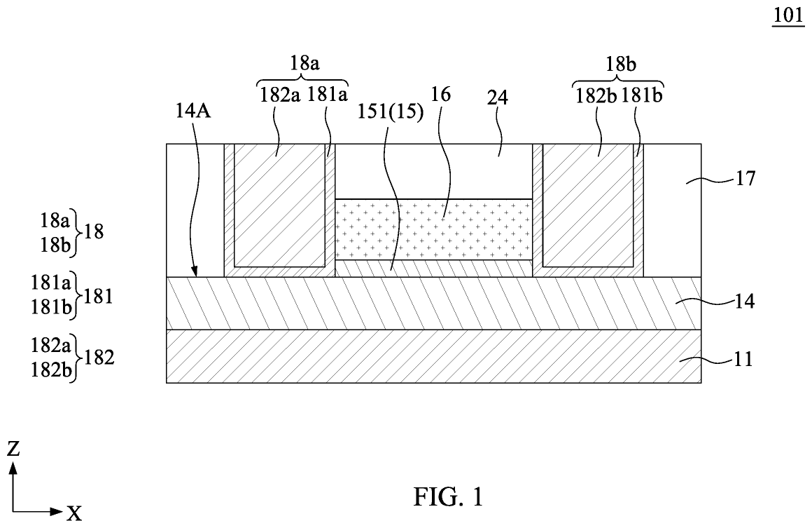

FIG. 1 is a schematic cross-sectional diagram of a semiconductor structure 101 in accordance with some embodiments of the present disclosure. The semiconductor structure 101 includes a gate layer 11, a ferroelectric layer 14, a high-k material layer 15, an oxide semiconductor 16, and a pair of source/drain structures 18. The semiconductor structure 101 can function as a ferroelectric memory unit, and can be disposed in an interconnect structure over a substrate (a detailed structure is provided below in descriptions of other embodiments). However, a position of the semiconductor structure 101 is not limited thereto.

The gate layer 11 can include conductive material or semiconductive material. In some embodiments, the gate layer 11 includes metallic material, such as aluminum, copper, tungsten, titanium, tantalum, tantalum aluminum, tantalum aluminum nitride, titanium nitride, tantalum nitride, nickel silicide, cobalt silicide, silver, tantalum carbide, tantalum silicon nitride, tantalum carbon nitride, titanium aluminum, titanium aluminum nitride, tungsten nitride, other suitable materials, metal alloys thereof, or combinations thereof. In some embodiments, the gate layer 11 includes oxide semiconductor material, such as indium tin oxide (ITO), aluminum-doped zinc oxide (AZO), or a combination thereof. The gate layer 11 can also be referred to as a word line or a word line structure. In some embodiments, the gate layer 11 extends along a first direction (e.g., X direction). A width and a thickness of the gate layer 11 can be adjusted according to a dimension of the semiconductor structure 101.

The ferroelectric layer 14 is disposed over the gate layer 11 along a second direction (e.g., Z direction), which is substantially orthogonal to the first direction. In some embodiments, the ferroelectric layer 14 covers an entirety of the gate layer 11. In some embodiments, a thickness of the ferroelectric layer 14 is in a range of 2 to 20 nanometers (nm) in order to provide enough polarization for a purpose of programming or erasing a memory unit. The ferroelectric layer 14 includes hafnium (Hf)-based ferroelectric material. In some embodiments, the ferroelectric layer 14 includes zirconium-doped hafnium oxide (HfZrO) (with a weight percentage of Zr in a range of 40% to 80%), hafnium aluminate (HfAlO), hafnium lanthanum oxide (HfLaO), hafnium cerium oxide (HfCeO), hafnium oxide (HfO), hafnium gadolinium oxide (HfGdO), hafnium silicon oxide (HfSiO), or a combination thereof.

The pair of source/drain structures 18 are disposed over the ferroelectric layer 14 along the second direction. The pair of source/drain structures 18 include a source structure (e.g., 18a) and a drain structure (e.g., 18b). The source structure 18a and the drain structure 18b may be respectively configured as a source line and a bit line of a memory unit. Each of the source structure 18a and the drain structure 18b can be a multi-layer structure. In some embodiments, the source structure 18a includes a first conductive layer 181a and a second conductive layer 182a surrounded by the first conductive layer 181a. In some embodiments, the first conductive layer 181a functions as a work function layer or an adhesion layer, and the second conductive layer 182a functions as the source line of the memory unit. In some embodiments, the second conductive layer 182a includes titanium, titanium nitride, copper, tungsten, tantalum, tantalum nitride, other suitable conductive materials, or a combination thereof. In some embodiments, a material of the first conductive layer 181a is selected from the candidate materials of the second conductive layer 182a, and the material of the first conductive layer 181a is different from the material of the second conductive layer 182a. The drain structure 18b may be a multi-layer structure similar to that of the source structure 18a. In some embodiments, the drain structure 18b includes a first conductive layer 181b and a second conductive layer 182b. The first conductive layer 181b and the second conductive layer 182b may be respectively similar to or same as the first conductive layer 181a and the second conductive layer 182a, and repeated description is omitted herein. In some embodiments, top surfaces of the source structure 18a and the drain structure 18b are substantially aligned or coplanar.

The oxide semiconductor 16 is disposed over the ferroelectric layer 14 along the second direction and laterally between the source/drain structures 18. In some embodiments, sidewalls of the oxide semiconductor 16 are in direct contact with sidewalls of the source/drain structures 18. In some embodiments, a material of the oxide semiconductor 16 includes indium zinc oxide (IZO), indium tin oxide (ITO), indium oxide (In₂O₃), gallium oxide (Ga₂O₃), indium gallium zinc oxide (InGaZnO), zinc oxide (ZnO), aluminum zinc oxide (Al₂O₅Zn₂), aluminum doped zinc oxide (AZO), indium tungsten oxide (InWO), titanium oxide (TiOx), gallium doped zinc oxide (GZO), indium zinc oxide (InZnO), indium silicon zinc oxide (InSiZnO), indium zinc tin oxide (InZnSnO), semiconductor materials including III-V materials, alloys including a combination of above materials, or a combination thereof. The oxide semiconductor 16 may function as a channel layer of the semiconductor structure 101. Carriers (e.g., oxygen) in the oxide semiconductor 16 may be attracted or released according to a state of polarization of the ferroelectric layer 14. In some embodiments, a thickness of the oxide semiconductor 16 is in a range of 0.5 to 12 nm for a purpose of programming and erasing a memory unit.

The source/drain structures 18 may be surrounded by a dielectric layer 17. In some embodiments, the dielectric layer 17 includes oxide, nitride, oxynitride, low-k dielectric materials, high-k dielectric materials, or a combination thereof. A top surface of the oxide semiconductor 16 can be below the top surfaces of the source/drain structures 18, and a dielectric layer 24 is disposed over the oxide semiconductor 16 along the second direction and between the source/drain structures 18 along the first direction. A material of the dielectric layer 24 may be same as or different from a material of the dielectric layer 17 depending on applications. In some embodiments, the material of the dielectric layer 24 is selected from the materials of the dielectric layer 17 listed above.

The high-k material layer 15 is disposed on a surface of the ferroelectric layer 14, for example, a top surface or a back surface of the ferroelectric layer 14. In some embodiments, the high-k material layer 15 is in direct contact with the surface of the ferroelectric layer 14. The high-k material layer 15 may include aluminum oxide (Al₂O₃), hafnium oxide (HfO₂), zirconium dioxide (ZrO₂), titanium dioxide (TiO₂), niobium oxide (Nb₂O₅), lanthanum oxide (La₂O₃), tungsten trioxide (WO₃), molybdenum trioxide (MoO₃), chromium tungsten oxide (CrWOₓ), or a combination thereof. In following description and as shown in FIGS. 1 to 6, high-k material layers 151, 152, 153 and 154 are different high-k material layers 15 in different embodiments (e.g., semiconductor structures 101 to 106) with different positions with respect to the ferroelectric layer 14.

As shown in FIG. 1, the high-k material layer 151 is disposed over a top surface 14A of the ferroelectric layer 14 and between the oxide semiconductor 16 and the ferroelectric layer 14. In some embodiments, the high-k material layer 151 is in direct contact with the top surface 14A of the ferroelectric layer 14. In some embodiments, the high-k material layer 151 is in direct contact with a bottom surface of the oxide semiconductor 16. In some embodiments, the high-k material layer 151 is in direct contact with the sidewalls of the source/drain structures 18. In some embodiments, an entirety of the high-k material layer 151 is between the source/drain structures 18. In some embodiments, the source/drain structures 18 are in direct contact with the ferroelectric layer 14, and more specifically, bottom surfaces of the source/drain structures 18 contact the top surface 14A of the ferroelectric layer 14. In some embodiments, a thickness of the high-k material layer 151 is in a range of 0.1 to 2 nm for a purpose of protection of the oxide semiconductor 16 and prevention of an on-state current issue. In some embodiments, the high-k material layer 151 is physically separated from the dielectric layer 17.

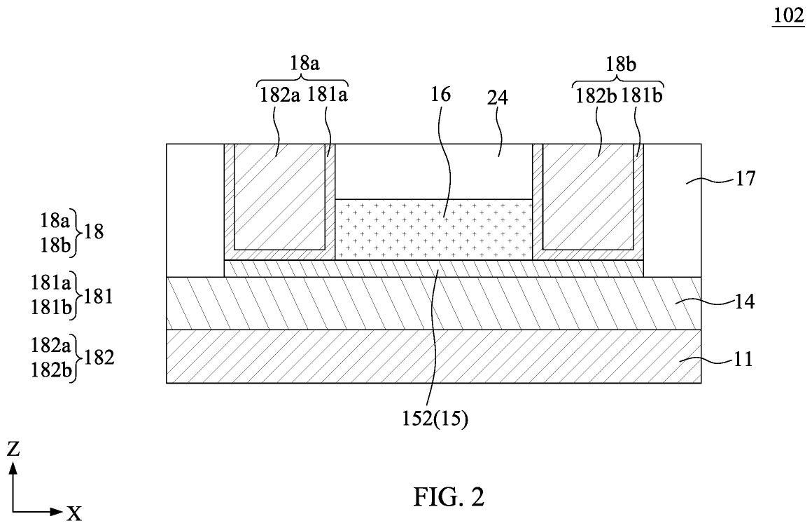

As shown in FIG. 2, the semiconductor structure 102 includes the high-k material layer 152 instead of the high-k material layer 151 of the semiconductor structure 101, wherein the high-k material layer 152 can be similar to the high-k material layer 151 but further extends below the source/drain structures 18. In some embodiments, the high-k material layer 152 is disposed between the source structure 18a and the ferroelectric layer 14, and between the drain structure 18b and the ferroelectric layer 14. In some embodiments, the high-k material layer 152 has a consistent thickness along the first direction. In some embodiments, the high-k material layer 152 is in direct contact with the top surface 14A of the ferroelectric layer 14. In some embodiments, the high-k material layer 152 is in direct contact with the bottom surface of the oxide semiconductor 16, a bottom surface of the source structure 18a, and a bottom surface of the drain structure 18b. In some embodiments, a sidewall of the high-k material layer 152 is aligned with a sidewall of the source structure 18a along the second direction. In some embodiments, a sidewall of the high-k material layer 152 is aligned with a sidewall of the drain structure 18b along the second direction. In some embodiments, an entirety of the high-k material layer 152 is within an area of a vertical projection of the source/drain structures 18 and the oxide semiconductor 16. In some embodiments, the source/drain structures 18 are physically separated from the ferroelectric layer 14 by the high-k material layer 152. In some embodiments, the sidewalls of the high-k material layer 152 are in physical contact with the dielectric layer 17. In some embodiments, a thickness of the high-k material layer 152 is in a range of 0.1 to 2 nm for a purpose of protection of the oxide semiconductor 16 and prevention of an on-state current issue.

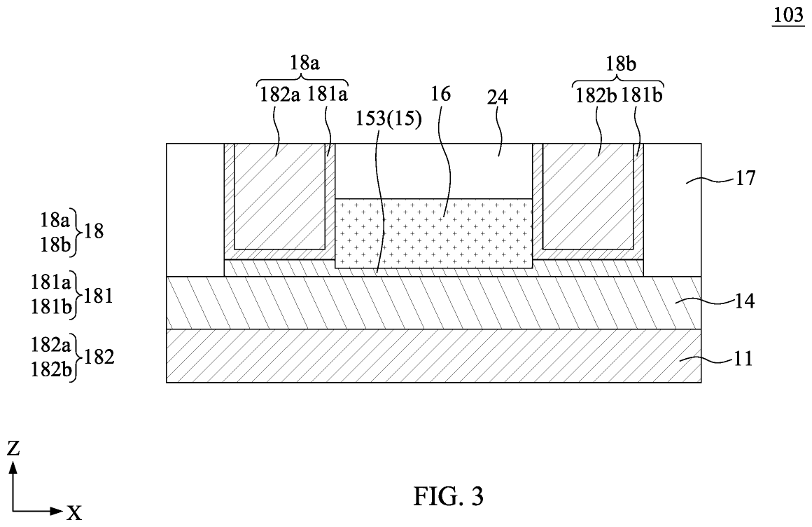

As shown in FIG. 3, the semiconductor structure 103 includes the high-k material layer 153, which is similar to the high-k material layer 152 but with inconsistent thicknesses along the first direction. In some embodiments, a thickness of a portion of the high-k material layer 153 below the oxide semiconductor 16 is less than thicknesses of portions of the high-k material layer 153 below the source/drain structures 18. In some embodiments, the thickness of the portion of the high-k material layer 153 below the oxide semiconductor 16 is in a range of 0.1 to 2 nm for a purpose of protection of the oxide semiconductor 16 and prevention of an on-state current issue. In some embodiments, the thicknesses of the portions of the high-k material layer 153 below the source/drain structures 18 are substantially equal. In some embodiments, each of the thicknesses of the portions of the high-k material layer 153 below the source/drain structures 18 is greater than the thickness of the portion of the high-k material layer 153 below the oxide semiconductor 16 by a range of 1 to 2 nm for a purpose of better protection of the source/drain structures 18 without affecting an efficiency of phase transition of the oxide semiconductor 16 induced by polarization of the ferroelectric layer 14.

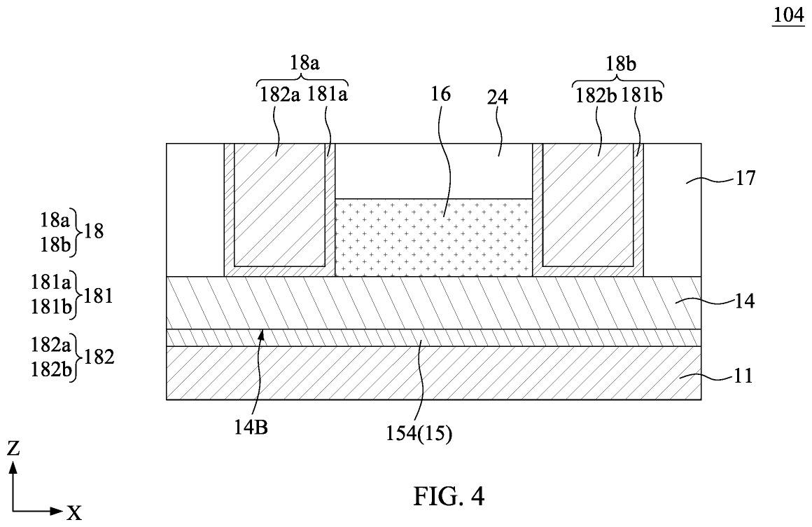

As shown in FIG. 4, the semiconductor structure 104 includes the high-k material layer 154, which is disposed on a bottom surface 14B of the ferroelectric layer 14. In some embodiments, the high-k material layer 154 is disposed between the ferroelectric layer 14 and the gate layer 11. In some embodiments, the high-k material layer 154 is in direct contact with the bottom surface 14B of the ferroelectric layer 14 and a top surface of the gate layer 11. In some embodiments, the high-k material layer 154 covers an entirety of the gate layer 11. In some embodiments, an entirety of the high-k material layer 154 is overlapped by the ferroelectric layer 14. In some embodiments, a thickness of the high-k material layer 154 is in a range of 0.1 to 2 nm for a purpose of reduction of defects on the bottom surface 14B of the ferroelectric layer 14 and enhanced polarization of the ferroelectric layer 14 induced by a voltage provided on the gate layer 11.

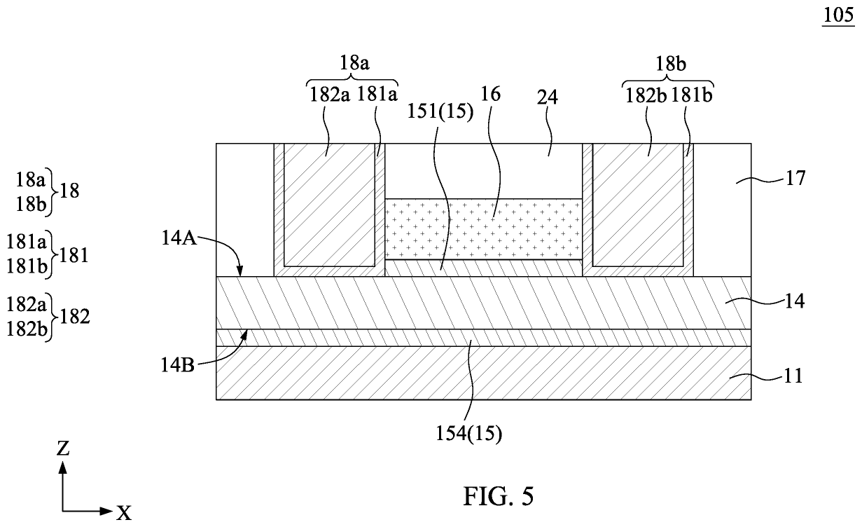

As shown in FIG. 5, the semiconductor structure 105 includes the high-k material layer 154 on the bottom surface 14B of the ferroelectric layer 14 and the high-k material layer 151 on the top surface 14A of the ferroelectric layer 14. FIG. 5 is an exemplary embodiment showing two different high-k material layers 15 that are both applied on the ferroelectric layer 14. In other embodiments, the high-k material layers 154 can be applied on the semiconductor structure 102 or 103 to provide different embodiments of the present disclosure.

Poor durability of a FeRAM is a challenge of FeRAM applications. According to some embodiments, defects of an oxide semiconductor at locations proximal to a ferroelectric layer, especially at an interface between the oxide semiconductor and the ferroelectric layer, are generated after cycles of programming and erasing. An electric field induced at a moment of polarization of the ferroelectric layer is too strong, which may cause defects in the oxide semiconductor proximal to the ferroelectric layer, especially on the surface where the oxide semiconductor contacts the ferroelectric layer, resulting in poor durability of a ferroelectric memory. A high-k material layer (e.g., the high-k material layer 151) disposed between a ferroelectric layer and an oxide semiconductor of the present disclosure can reduce impact of the electric field on the oxide semiconductor, and defects of the oxide semiconductor induced by the electric field can thereby be reduced. Durability of a ferroelectric memory unit can thereby be improved.

In addition, according to some embodiments, a carrier density of the oxide semiconductor at locations proximal to the ferroelectric layer changes in accordance with the polarization of the ferroelectric layer, and an electric field induced at a moment of the change of the carrier density may also cause defect in the ferroelectric layer, especially around the surface where the ferroelectric layer contacts the oxide semiconductor, which can also be a factor contributing to the poor durability of the ferroelectric memory. Therefore, the high-k material layer presented between the ferroelectric layer and the oxide semiconductor not only protects the oxide semiconductor but also prevents or reduces defects of the ferroelectric layer.

Similar concepts can be applied to an interface between the ferroelectric layer and a source/drain structure disposed thereover, and an interface between the ferroelectric layer and a gate layer disposed thereunder. A high-k material layer (e.g., the high-k material layer 152 or 153) disposed between the ferroelectric layer and the source/drain structure of the present disclosure can protect surfaces of the ferroelectric layer overlapped by the source/drain structure. A high-k material layer (e.g., the high-k material layer 154) disposed between the ferroelectric layer and the gate layer of the present disclosure can protect a bottom surface of the ferroelectric layer overlapping the gate layer. Durability of a ferroelectric memory unit can thereby be improved.

A greater thickness of the high-k material layer 15 may result in an on-state current issue, which is also known as equivalent oxide thickness (EOT) effect. The thickness of the high-k material layer 15 is controlled to be substantially equal to or less than 2 nm for a purpose of prevention of the EOT effect. In order to further suppress the EOT effect and enhance protection of the oxide semiconductor 16 by the high-k material layer 15, the oxide semiconductor 16 can include multiple layers with different carrier concentrations, wherein a layer having a greater carrier concentration is proximal to the ferroelectric layer 14.

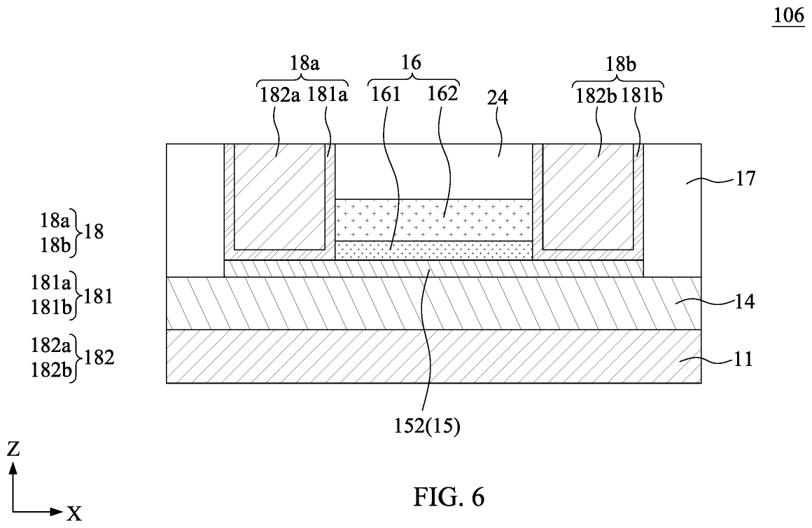

FIG. 6 is a schematic cross-sectional diagram of a semiconductor structure 106 in accordance with some embodiments of the present disclosure. The semiconductor structure 106 is similar to the semiconductor structure 102, but the semiconductor structure 106 includes a multi-layer oxide semiconductor 16. In some embodiments, the oxide semiconductor 16 includes a first oxide semiconductor layer 161 and a second oxide semiconductor layer 162 disposed over the first oxide semiconductor layer 161 along the second direction. In some embodiments, the second oxide semiconductor layer 162 is in direct contact with the first oxide semiconductor layer 161. In some embodiments, the first oxide semiconductor layer 161 is proximal to the high-k material layer 152. In some embodiments, the first oxide semiconductor layer 161 is in direct contact with the high-k material layer 152.

The first oxide semiconductor layer 161 has a carrier concentration greater than that of the second oxide semiconductor layer 162. In some embodiments, the carrier concentration of the first oxide semiconductor layer 161 is about 3*10¹⁸ to 1*10²⁰ per cubic centimeter (cm⁻³) for current enhancement with high mobility. A higher carrier concentration of the first oxide semiconductor layer 161 can also improve ferroelectric polarization (e.g., increase dipole charges) without additional defect charge formation. In some embodiments, the carrier concentration of the second oxide semiconductor layer 162 is about 1*10¹⁶ to 1*10¹⁸ cm⁻³ for threshold voltage control. In some embodiments, a ratio between the carrier concentrations of the first oxide semiconductor layer 161 and the second oxide semiconductor layer 162 is in a range of 1*10 to 1*10² cm⁻³. A thickness of the second oxide semiconductor layer 162 is about 3-5 times a thickness of the first oxide semiconductor layer 161. In some embodiments, the thickness of the first oxide semiconductor layer 161 is in a range of 0.5 to 2 nm. In some embodiments, the thickness of the second oxide semiconductor layer 162 is in a range of 1.5 to 10 nm.

The high-k material layer of the present disclosure can protect the adjacent ferroelectric layer overlapping the gate layer, and durability of the ferroelectric memory unit can thereby be improved. However, an excessive thickness of the high-k material layer may lead to on-state current issues as illustrated above. In addition to precisely control the thickness of the high-k material layer, the first oxide semiconductor layer 161 having a higher concentration may have advantage to elevate on-state current but may have negative influence on threshold voltage. The presence of the second oxide semiconductor layer 162 having a lower concentration and a thickness about 3-5 times of that of the first oxide semiconductor layer 161 can mitigate the negative influence on threshold voltage of the first oxide semiconductor layer 161. Therefore, the combination of the oxide semiconductor layers 161 and 162 can keep or improve the threshold voltage and the on-state current of the ferroelectric memory unit.

In some embodiments, the second oxide semiconductor layer 162 includes gallium oxide (Ga₂O₃), gallium doped zinc oxide (GZO), indium gallium zinc oxide (InGaZnO), indium silicon zinc oxide (InSiZnO), indium zinc tin oxide (InZnSnO), indium tungsten oxide (InWO), or a combination thereof. In some embodiments, a material of the first oxide semiconductor layer 161 is selected from one or more of a group of the materials listed in the previous sentence. In some embodiments, the first oxide semiconductor layer 161 includes zinc oxide (ZnO), indium tungsten oxide (InWO), indium gallium zinc oxide (InGaZnO), indium zinc oxide (InZnO), indium tin oxide (ITO), or a combination thereof. In some embodiments, a material of the second oxide semiconductor layer 162 is selected from one or more of a group of the materials listed in the previous sentence. In some embodiments in which the oxide semiconductor layers 161 and 162 are both comprised of InWO, a concentration of W in the second oxide semiconductor layer 162 is substantially greater than a concentration of W in the first oxide semiconductor layer 161. In some embodiments in which the oxide semiconductor layers 161 and 162 are both comprised of InGaZnO, a concentration of Ga in the second oxide semiconductor layer 162 is substantially greater than a concentration of Ga in the first oxide semiconductor layer 161. In some embodiments in which the oxide semiconductor layers 161 and 162 are both comprised of InGaZnO, a concentration of In in the second oxide semiconductor layer 162 is substantially less than a concentration of In in the first oxide semiconductor layer 161.

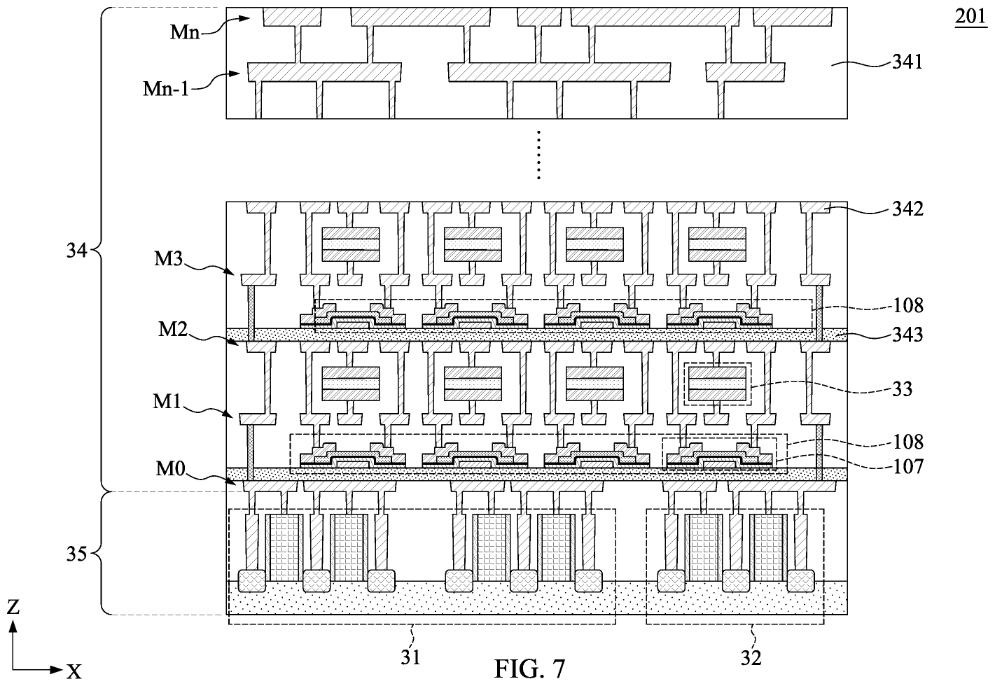

FIG. 7 is a schematic cross-sectional diagram of a semiconductor structure 201 in accordance with some embodiments of the present disclosure, wherein the semiconductor structure 201 includes a memory unit 107 disposed in an interconnect structure 34 over a substrate 35. In some embodiments, the substrate 35 includes a semiconductive layer, a plurality of electrical components formed on the semiconductive layer, and an insulating layer surrounding the electrical components. The semiconductive layer may include a bulk semiconductor material, such as silicon, or other semiconductor materials, such as silicon germanium, silicon carbide, gallium arsenide, or the like. The semiconductive layer may be of a first conductivity type, e.g., a P-type semiconductive substrate (acceptor type), or a second conductivity type, e.g., an N-type semiconductive substrate (donor type).

The plurality of electrical components may be formed on the semiconductive layer using suitable methods of manufacturing semiconductors. The electrical components can be active components or devices, and may include different types or generations of devices. The electrical components can include a central circuit 31, such as a logic circuit or a SRAM array, and a peripheral circuit 32, such as an input-output (IO) circuit or an analog circuit. In some embodiments, the peripheral circuit 32 surrounds the central circuit 31.

The insulating layer of the substrate 35 may be formed over the semiconductive layer, and the interconnect structure 34 is formed over the insulating layer. The interconnect structure 34 includes a plurality of conductive features 342 surrounded by a plurality of intermetal dielectric (IMD) layers 341. In some embodiments, the conductive features 342 include tungsten (W), aluminum (Al), copper (Cu), silver (Ag), gold (Au), titanium (Ti), tantalum (Ta), ruthenium (Ru), titanium-nitride (TiN), tantalum-nitride (TaN), ruthenium nitride (RuN), tungsten nitride (WN), and alloys thereof. In some embodiments, a plurality of contacts penetrate the insulating layer to electrically connect the electrical components. The plurality of contacts may provide electrical connection between the electrical components and the conductive features 342 of different electrical paths. The conductive features 342 include a plurality of metal line layers M0 to Mn, wherein n is a positive integer greater than 1, and a plurality of metal via layers, alternately arranged between the plurality of metal line layers M0 to Mn for electrical connection between the metal line layers.

The semiconductor structure 201 includes multiple memory units 107, and the memory units 107 together form a memory array 108. The memory array 108 can be disposed between the metal line layers proximal to the substrate 35. In some embodiments, the memory array 108 is disposed between the metal line layer M0 and the metal line layer M1. In some embodiments, the memory array 108 is disposed between the metal line layer M2 and the metal line layer M3. In some embodiments, the interconnect structure 34 further includes a planarization layer 343 disposed below the memory array 108 for a purpose of providing a planar surface for formation of the memory array 108. In some embodiments, the semiconductor structure 201 further includes a plurality of capacitor structures 33 disposed in the interconnect structure 34. In some embodiments, each of the capacitor structures 33 is disposed above one of the memory units 107. In some embodiments, each of the capacitor structures 33 is vertically aligned with one of the memory units 107.

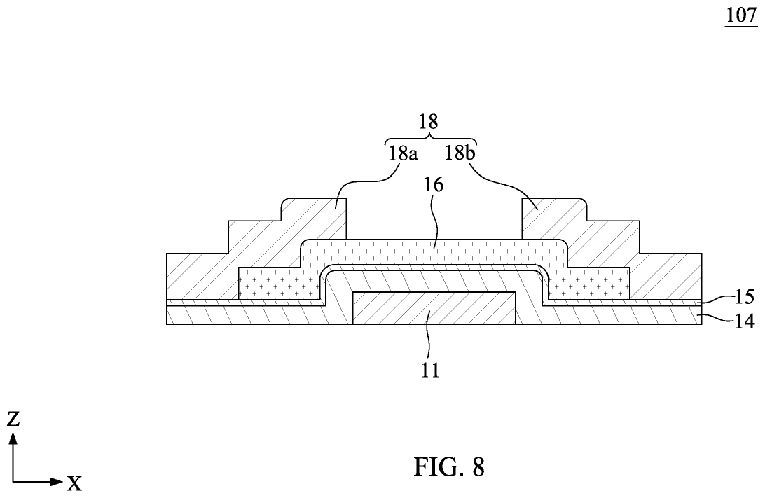

FIG. 8 is a schematic cross-sectional diagram of the memory unit 107 of the semiconductor structure 201 in accordance with some embodiments of the present disclosure. The memory unit 107 can be similar to one of the semiconductor structures 101 to 106 as described above, but the memory unit 107 includes a ferroelectric layer 14 being conformal to a gate layer 11. In some embodiments, the ferroelectric layer 14 covers a top surface and sidewalls of the gate layer 11. In some embodiments, the ferroelectric layer 14 further extends laterally to the gate layer 11, and an extension of the ferroelectric layer 14 is at a level same as a level of the gate layer 11. In some embodiments, a high-k material layer 15 is disposed over and conformal to the ferroelectric layer 14. In some embodiments, the high-k material layer 15 covers the extension of the ferroelectric layer 14. In some embodiments, an oxide semiconductor 16 is disposed over and conformal to the high-k material layer 15. In some embodiments, the oxide semiconductor 16 overlaps a portion of the extension of the ferroelectric layer 14 and exposes a portion of the high-k material layer 15 covering the extension of the ferroelectric layer 14. In some embodiments, source/drain structures 18 are disposed over the oxide semiconductor 16 and contact the exposed portion of the high-k material layer 15. In some embodiments, a portion of the oxide semiconductor 16 vertically over the gate layer 11 is exposed through the source/drain structures 18. In some embodiments, the source/drain structures 18 cover peripheral portions of the oxide semiconductor 16. In some embodiments, the source/drain structures 18 contact an entirety of sidewalls of the oxide semiconductor 16. In some embodiments, the source/drain structures 18 overlap a stepped portion of the oxide semiconductor 16, wherein the stepped portion of the oxide semiconductor 16 corresponds to and conforms to the sidewalls of the gate layer 11. In some embodiments, a sidewall of the source structure 18a, a sidewall of the high-k material layer 15, and a sidewall of the ferroelectric layer 14 are substantially aligned along the second direction. In some embodiments, a sidewall of the drain structure 18b, a sidewall of the high-k material layer 15, and a sidewall of the ferroelectric layer 14 are substantially aligned along the second direction.

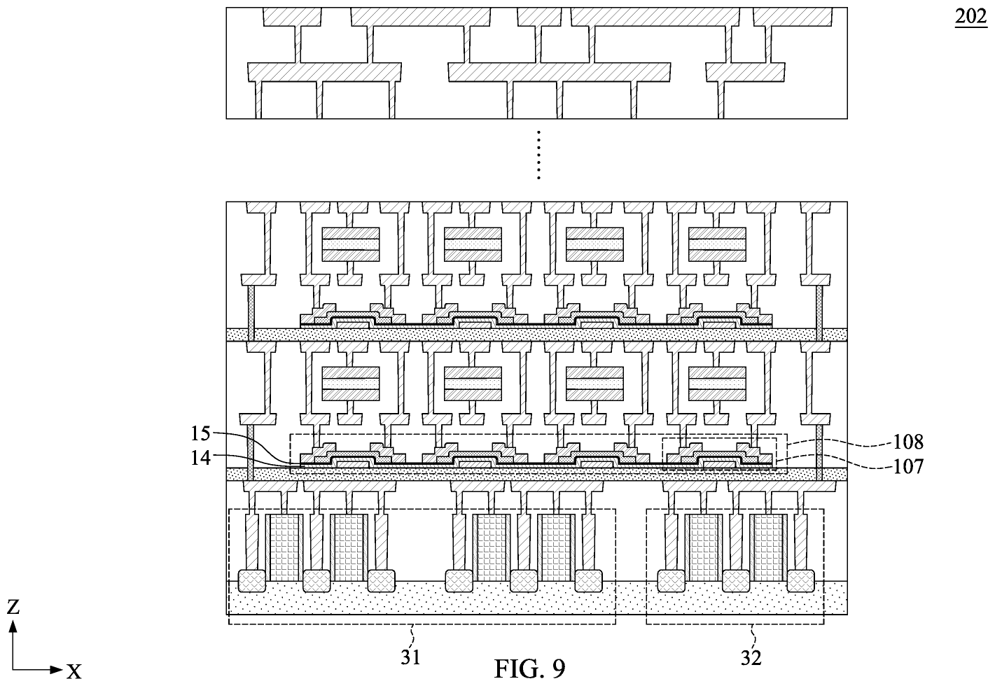

FIG. 9 is a schematic cross-sectional diagram of a semiconductor structure 202 in accordance with some embodiments of the present disclosure. The semiconductor structure 202 is similar to the semiconductor structure 201, except that, in the semiconductor structure 202, ferroelectric layers 14 of adjacent memory units 107 are connected. In some embodiments, the ferroelectric layers 14 of all memory units 107 of the memory array 108 are a monolithic structure, which extends across an entirety of the memory array 108. In some embodiments, high-k material layers 15 of adjacent memory units 107 of the memory array 108 are also connected. In some embodiments, the high-k material layers 15 of all the memory units 107 of the memory array 108 are a monolithic structure, which extends across an entirety of the memory array 108.

It should be noted that the memory unit 107 shown in FIGS. 7 and 9 are for a purpose of illustration. The semiconductor structures 101 to 106 can be applied in the semiconductor structures 201 and 202 shown in FIGS. 7 and 9 as well. In some embodiments, the dielectric layers 17 and 24 include a same dielectric material. In some embodiments, the dielectric layers 17 and 24 are replaced by the IMD layers 341 when the semiconductor structures 101 to 106 are applied in the semiconductor structures 201 or 202 shown in FIGS. 7 and 9.

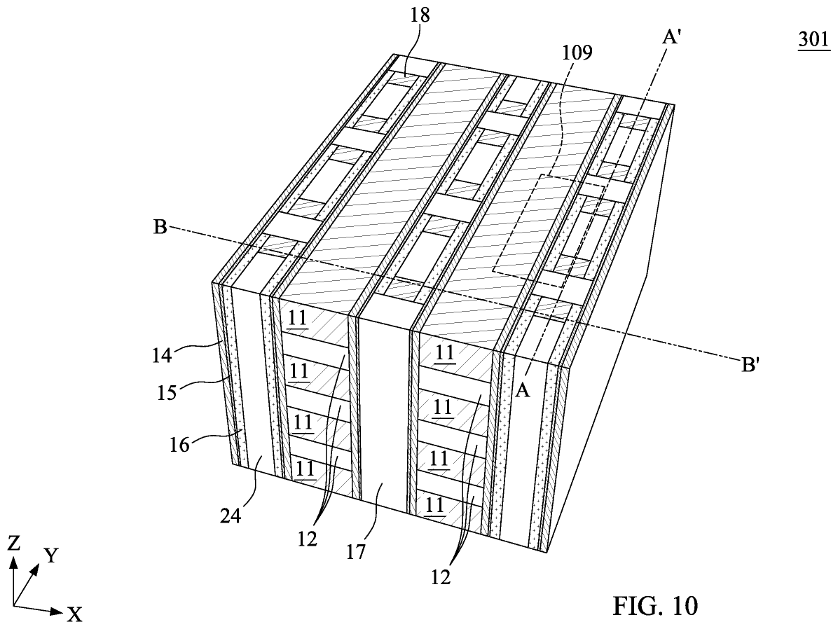

FIG. 10 is a three dimensional (3D) diagram of a semiconductor structure 301 in accordance with some embodiments of the present disclosure. The semiconductor structure 301 includes a plurality of gate layers 11 stacked along the second direction, wherein adjacent gate layers 11 are separated by an isolating layer 12. In some embodiments, the ferroelectric layer 14, the high-k material layer 15, the oxide semiconductor 16, and source/drain structures 18 are stacked over the gate layers 11 along the first direction. The semiconductor structure 301 includes a plurality of memory units 109. In some embodiments, the semiconductor structure 301 is a 3D memory array.

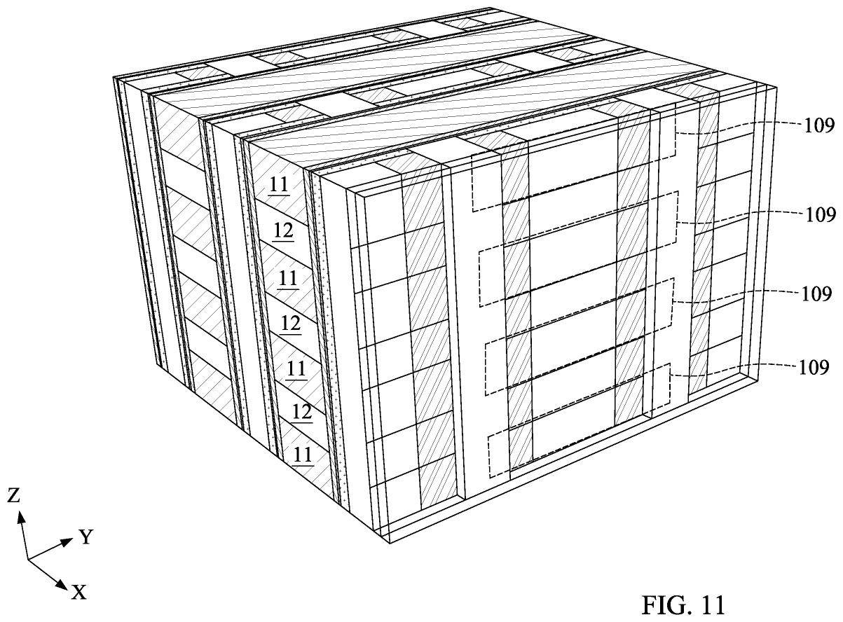

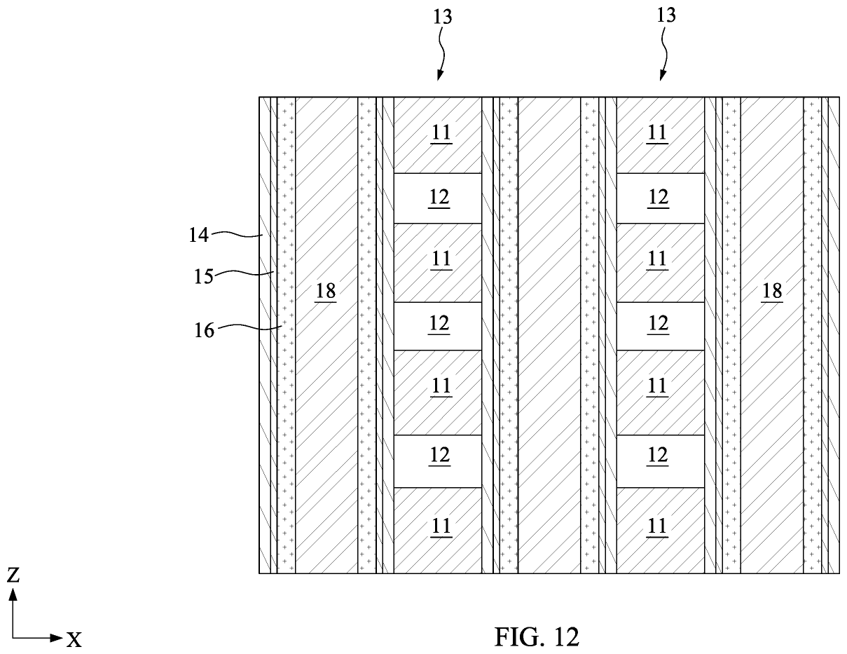

FIG. 11 is a 3D diagram of a portion of the semiconductor structure 301 cut along a line A-A′ in accordance with some embodiments of the present disclosure. FIG. 11 shows the semiconductor structure 301 including multiple memory units 109 stacked along the second direction. FIG. 12 is a cross-sectional diagram of the semiconductor structure 301 along a line B-B′ in accordance with some embodiments of the present disclosure. In some embodiments, each of the source/drain structures 18 extends along the second direction. In some embodiments, the oxide semiconductor 16, the high-k material layer 15 and the ferroelectric layer 14 are sequentially arranged on a sidewall of the source/drain structure 18 along the first direction. In some embodiments, each of the oxide semiconductor 16, the high-k material layer 15 and the ferroelectric layer 14 extends along the second direction. In some embodiments, the gate layers 11 and the isolating layers 12 are alternately arranged to define a stack structure 13. In some embodiments, a source/drain structure 18 is sandwiched between adjacent stack structures 13 along the first direction. In some embodiments, the oxide semiconductor 16, the high-k material layer 15 and the ferroelectric layer 14 are sandwiched between the stack structure 13 and the source/drain structure 18 along the first direction.

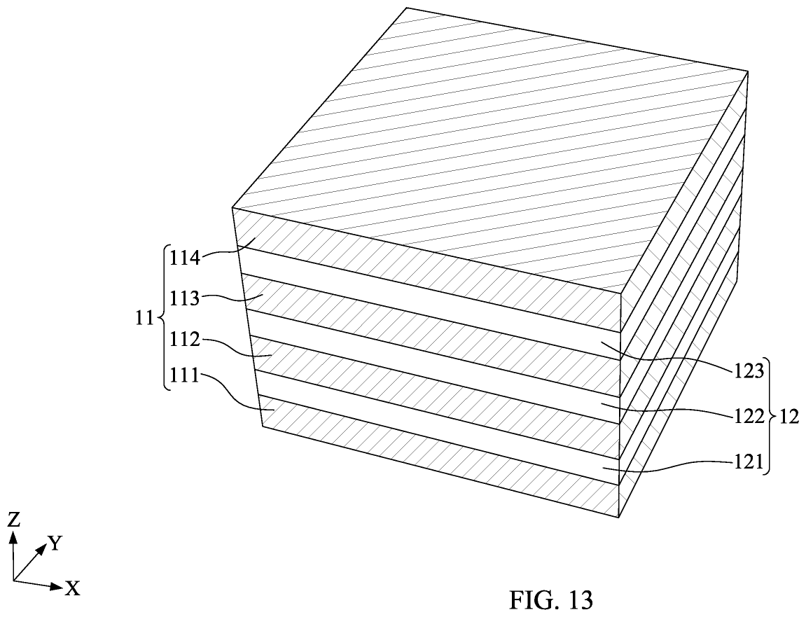

FIGS. 13 to 21 are schematic 3D diagrams of the semiconductor structure 301 at different stages of a manufacturing method in accordance with some embodiments of the present disclosure.

Referring to FIG. 13, a plurality of gate layers 11 (including gate layers 111, 112, 113 and 114) and a plurality of isolating layers 12 (including isolating layers 121, 122 and 123) are alternately arranged. In some embodiments, the gate layers 11 and the isolating layers 12 are formed over a substrate (e.g., the substrate 35 in FIG. 7). The gate layers 11 may include a conductive material (e.g., a metallic component) or a semiconductive material (e.g., an oxide semiconductor). The isolating layers 12 may include oxide, nitride, oxynitride, low-k dielectric materials, or a combination thereof. The gate layers 11 and the isolating layers 12 may be formed using a suitable process, such as atomic layer deposition (ALD), chemical vapor deposition (CVD), physical vapor deposition (PVD), plasma-enhanced PVD (PEPVD), plasma-enhanced ALD (PEALD), or a combination thereof.

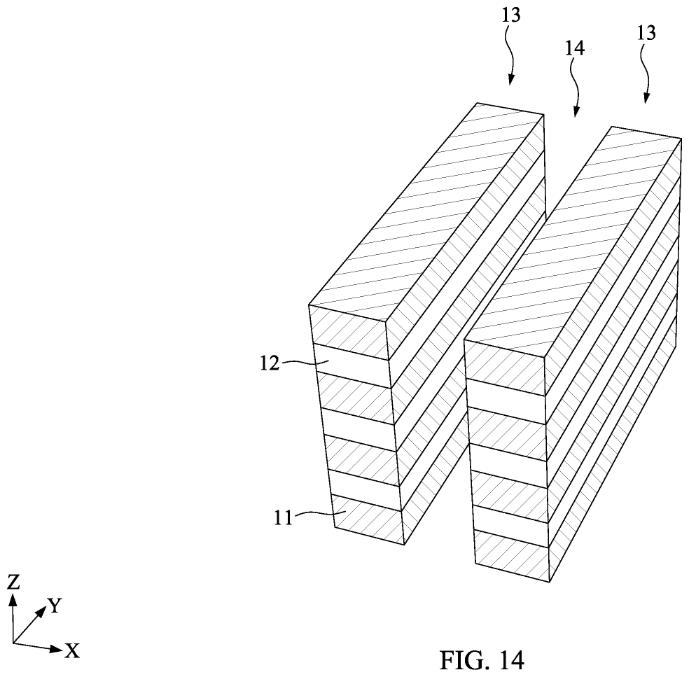

Referring to FIG. 14, a patterning operation is performed on the gate layers 11 and the isolating layers 12 to form a plurality of stacked structures 13. A trench 41 is formed by the patterning operation between adjacent stacked structures 13. In some embodiments, the trench 41 penetrates the gate layers 11 and the isolating layers 12. The patterning operation can include multiple steps, such as forming a patterned mask layer to define a position of the trench 41, and performing multiple cycles of etching operations to remove portions of the gate layers 11 and the isolating layers 12 using the patterned mask layer as a mask. The patterned mask layer is not shown in the figures. In some embodiments, the patterned mask layer is removed after the performance of the multiple cycles of etching operations. The etching operations can include dry etching operations, wet etching operations, or a combination thereof depending on different applications.

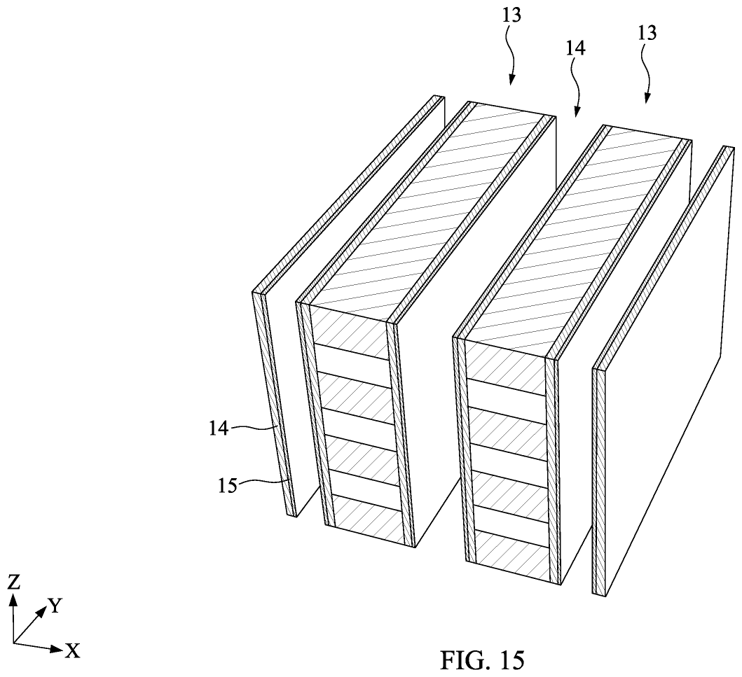

Referring to FIG. 15, a ferroelectric layer 14 and a high-k material layer 15 are sequentially formed over sidewalls of the stacked structures 13 (i.e., sidewalls of the trenches 41). In some embodiments, a ferroelectric material is formed covering the stacked structures 13 and conformal to a profile of the stacked structures 13, and horizontal portions of the ferroelectric material are removed to form the ferroelectric layer 14. In some embodiments, the ferroelectric layer 14 covers only the sidewalls of the stacked structures 13. In other words, the ferroelectric layer 14 is formed on the sidewalls of the trenches 41. The ferroelectric layer 14 includes a plurality of portions arranged along the first direction, and each portion extends along the second direction. In some embodiments, the ferroelectric layer 14 is formed by PVD, ALD, PEPVD, or PEALD.

The high-k material layer 15 may be formed after the formation of the ferroelectric layer 14. In some embodiments, a high-k dielectric material is formed covering the ferroelectric layer 14 and the stacked structures 13. In some embodiments, the high-k dielectric material is conformal to a profile of a combination of the stacked structures 13 and the ferroelectric layer 14, and horizontal portions of the high-k dielectric material are removed to form the high-k material layer 15. In some embodiments, the high-k material layer 15 covers only lateral surfaces of the ferroelectric layer 14. In other words, the high-k material layer 15 is formed on the sidewalls of the trenches 41 after the formation of the ferroelectric layer 14. In some embodiments, the high-k material layer 15 is formed by PVD, ALD, PEPVD, PEALD, or a combination thereof.

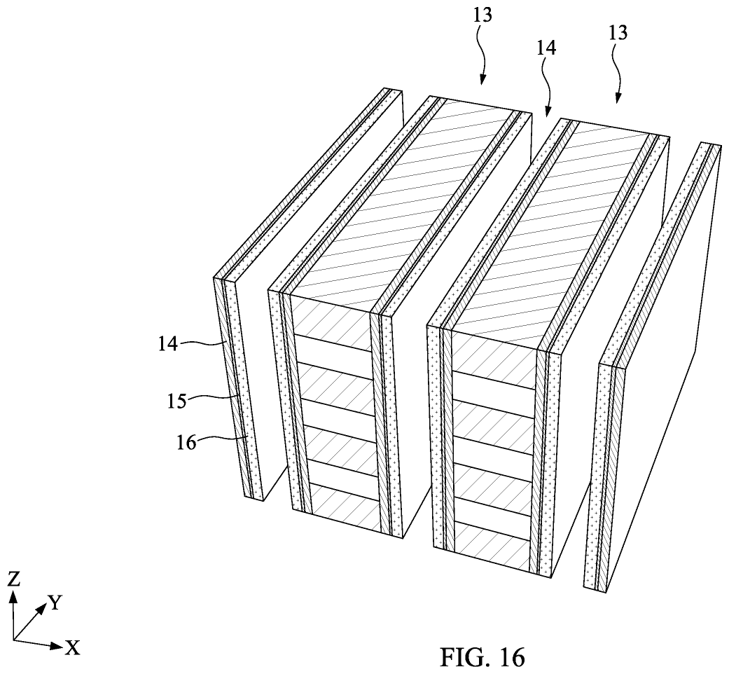

Referring to FIG. 16, an oxide semiconductor 16 is formed on the sidewalls of the stacked structures 13 (i.e., the sidewalls of the trenches 41) after the formation of the high-k material layer 15. The formation of the oxide semiconductor 16 can be similar to the formation of the ferroelectric layer 14 or the high-k material layer 15. In some embodiments, the oxide semiconductor 16 is formed by PVD, ALD, PEPVD, PEALD, or a combination thereof.

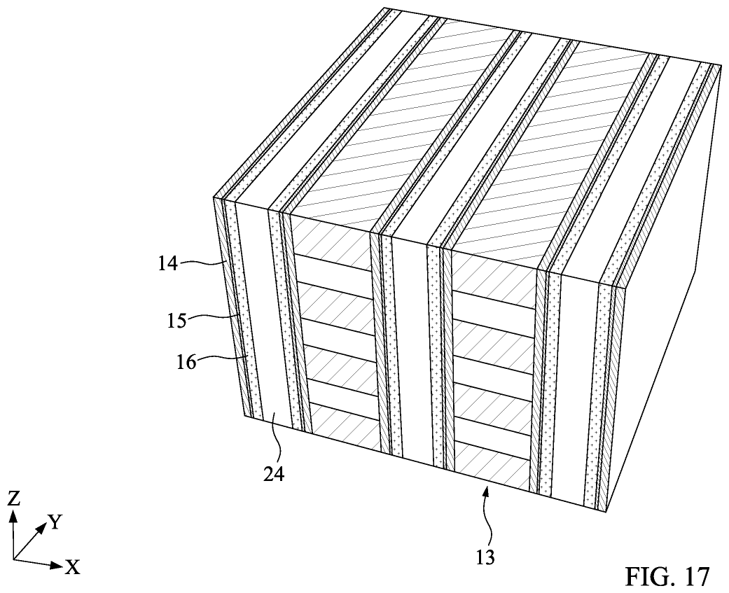

Referring to FIG. 17, a dielectric layer 24 is formed to fill the trenches 41. In some embodiments, a planarization is performed after a deposition of the dielectric layer 24. In some embodiments, after the planarization, a top surface of the dielectric layer 24 is substantially aligned or coplanar with top surfaces of the stacked structures 13. In some embodiments, the dielectric layer 24 fills each of the trenches 41 shown in FIG. 16. In some embodiments, the dielectric layer 24 is formed by CVD, PVD, ALD, PEPVD, PEALD, or a combination thereof.

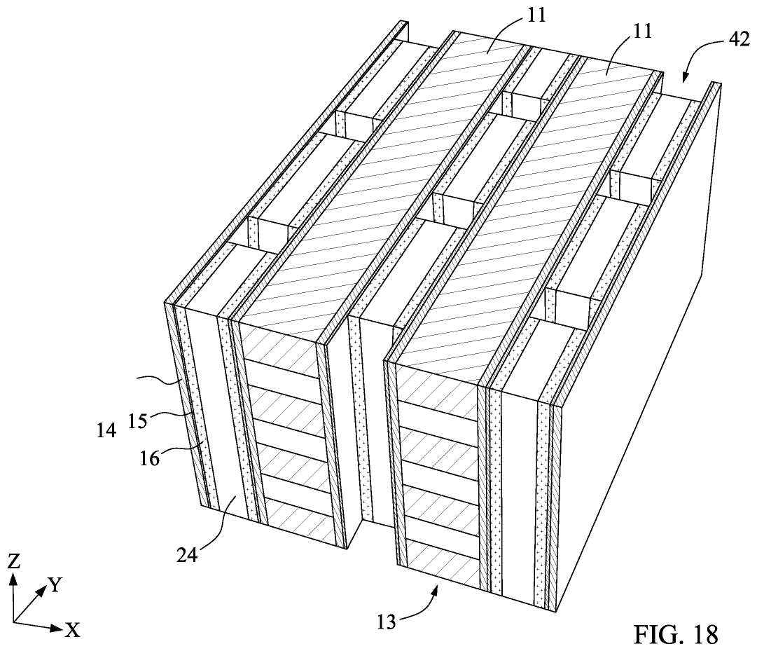

Referring to FIG. 18, a patterning operation is performed to form a plurality of trenches 42 between adjacent stacked structures 13. In some embodiments, the patterning operation includes one or more etching operations performed on the dielectric layer 24 and the oxide semiconductor 16. In some embodiments, the one or more etching operations have a high selectivity to the materials of the dielectric layer 24 and the oxide semiconductor 16. In some embodiments, the one or more etching operations have a low selectivity to the materials of the high-k material layer 15, the ferroelectric layer 14 and the gate layers 11. In some embodiments, at least an etchant of the one or more etching operations has a high removal rate to the material of the oxide semiconductor 16 and a low (or zero) removal rate to the material of the high-k material layer 15. In some embodiments, portions of the high-k material layer 15 are exposed by the trenches 42. In some embodiments, the trenches 42 are arranged into multiple rows, wherein each row of the trenches 42 extends along a third direction (e.g., Y direction), which is substantially orthogonal to the first direction and the second direction. In some embodiments, the trenches 42 in adjacent rows are offset or alternately arranged along the first direction for a purpose of an electrical connection to a source line or a bit line (details of which are provided below). The patterning operation cuts the oxide semiconductor 16 into portions corresponding to a number of memory units to be formed. The patterning operation may also cut the dielectric layer 24 into portions corresponding to a number of the portions of the oxide semiconductor 16. In some embodiments, each of the portions of the dielectric layer 24 is sandwiched by two portions of the oxide semiconductor 16.

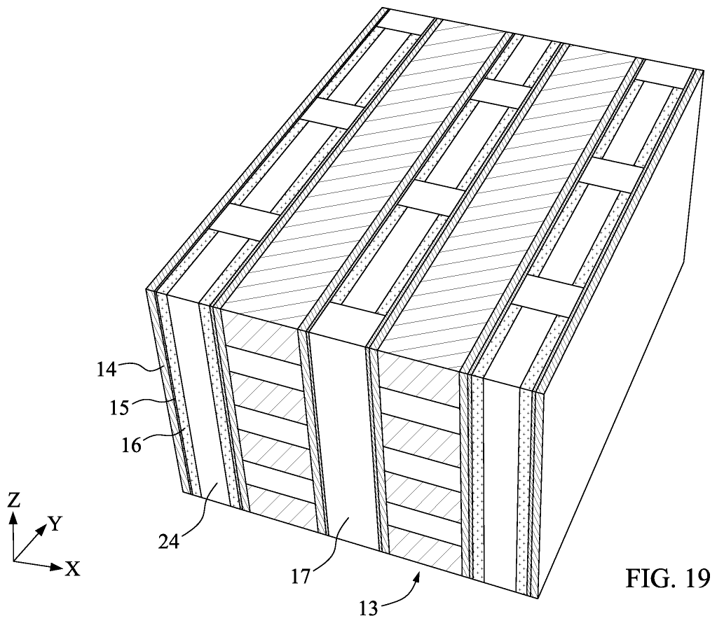

Referring to FIG. 19, a dielectric layer 17 is formed to fill the trenches 42 shown in FIG. 18. Similar to the formation of the dielectric layer 24, a planarization may be performed to provide a planar top surface of the dielectric layer 17. In some embodiments, the top surface of the dielectric layer 17 is substantially aligned or coplanar with the top surface of the dielectric layer 24. The dielectric layer 17 separates the oxide semiconductors 16 of different memory units.

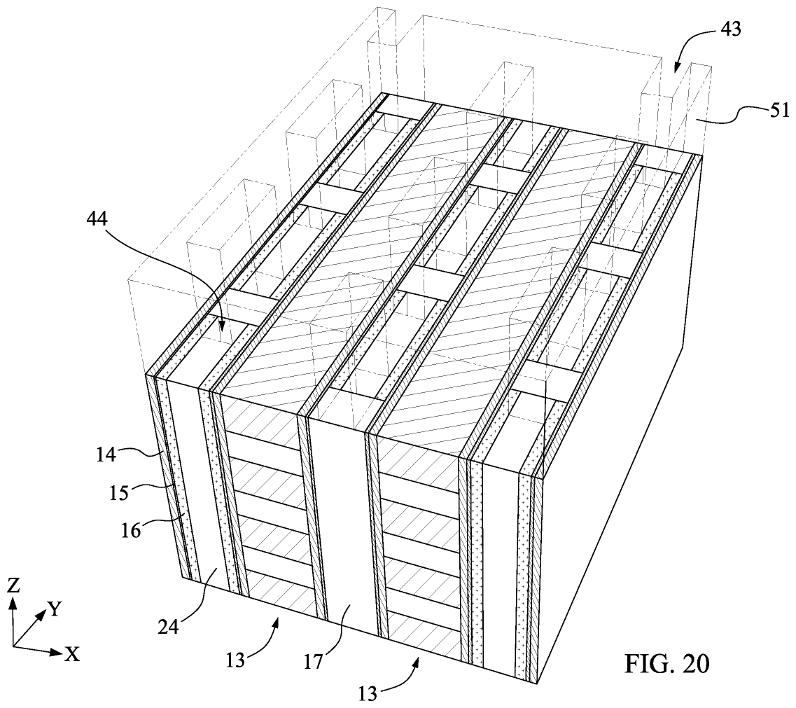

Referring to FIG. 20, a patterned mask layer 51 is formed over the stacked structures 13, the ferroelectric layer 14, the high-k material layer 15, the oxide semiconductor 16, and the dielectric layers 17 and 24. An etching operation is performed using the patterned mask layer 51 as a mask to form a plurality of trenches 44 on lateral sides of the dielectric layer 17 for formation of source/drain structures 18 in subsequent processes. In some embodiments, the etching operation has a high etch rate selectivity of a material of the dielectric layer 24 with respect to a material of the dielectric layer 17. In some embodiments, the patterned mask layer 51 includes a plurality of openings 43 exposing the dielectric layer 17 and portions of the dielectric layer 24 on two opposite sides of each segment of the dielectric layer 17. Since the etching operation has a low selectivity to the dielectric layer 17, a pair of the trenches 44 are aligned with each other on two opposite sides of every segment of the dielectric layer 17. In some embodiments, portions of the dielectric layer 24 contacting the dielectric layer 17 are removed. In some embodiments, portions of the oxide semiconductor 16 proximal to the dielectric layer 17 are exposed by the trenches 44.

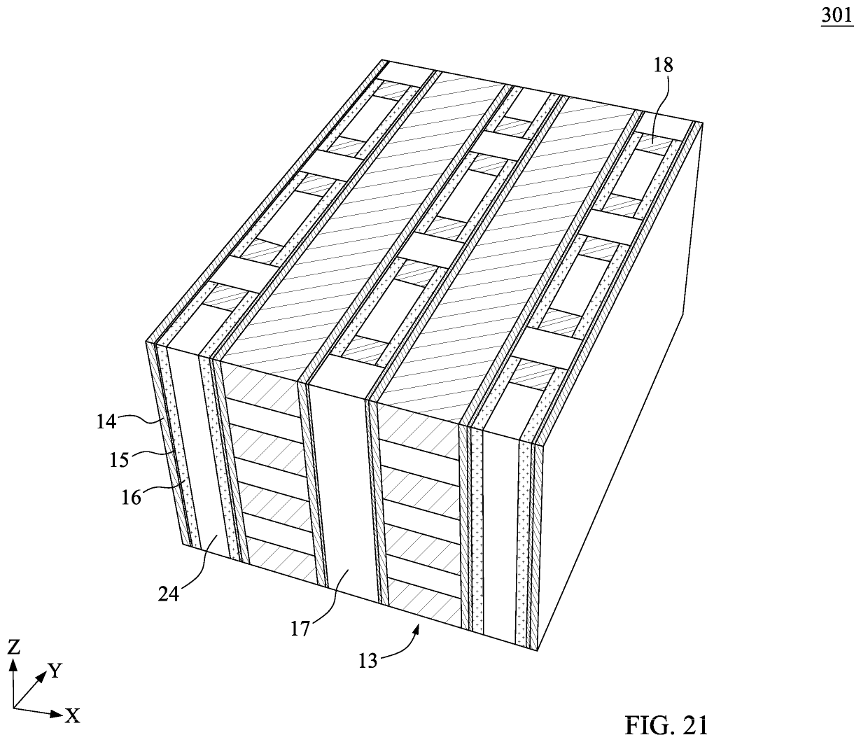

Referring to FIG. 21, one or more conductive materials are deposited to fill the trenches 44, thus forming source/drain structures 18, and the semiconductor structure 301 is thereby formed. Each of the portions of the oxide semiconductor 16 contacts a pair of the source/drain structures 18 (including a source structure and a drain structure). The semiconductor structure 301 includes the oxide semiconductor 16 sandwiched between the source/drain structure 18 and the high-k material layer 15. However, the present disclosure is not limited thereto. Similar to the embodiments as described above and illustrated in FIGS. 1 to 6, the source/drain structure 18 can be in direct contact with the high-k material layer 15 and the oxide semiconductor 16 can extend contiguously across different memory units between the source structure 18a and the drain structure 18b.

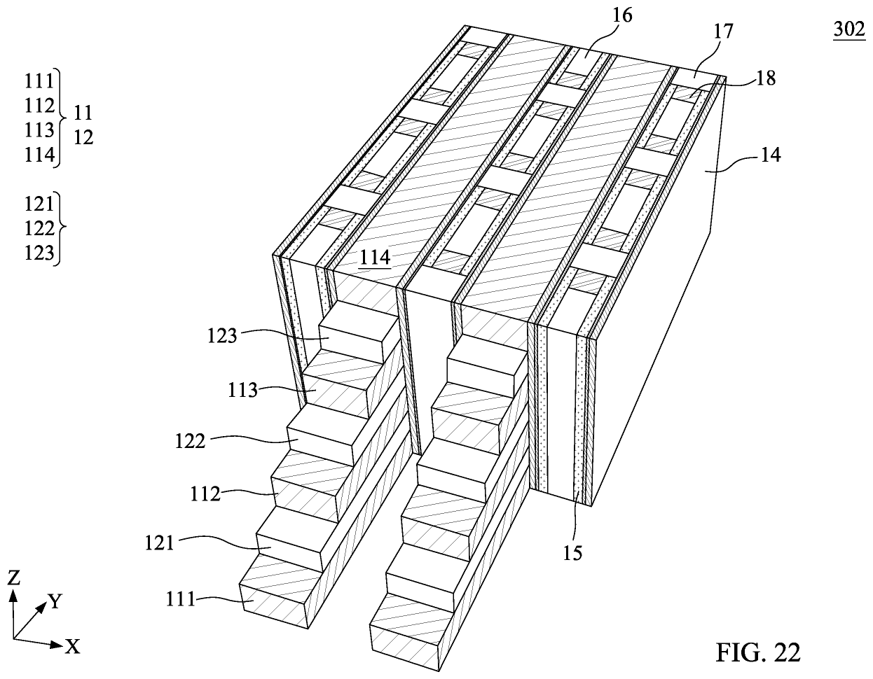

FIG. 22 is a schematic 3D diagram of a semiconductor structure 302 in accordance with some embodiments of the present disclosure. The semiconductor structure 302 is similar to the semiconductor structure 301, but the semiconductor structure 302 further includes a stair configuration of the stacked structure 13 outside the region of the memory array. In some embodiments, cycles of etching operations are performed on the stacked structure 13 outside the region of the memory array after the operations as depicted in FIG. 21 for a purpose of electrical connection.

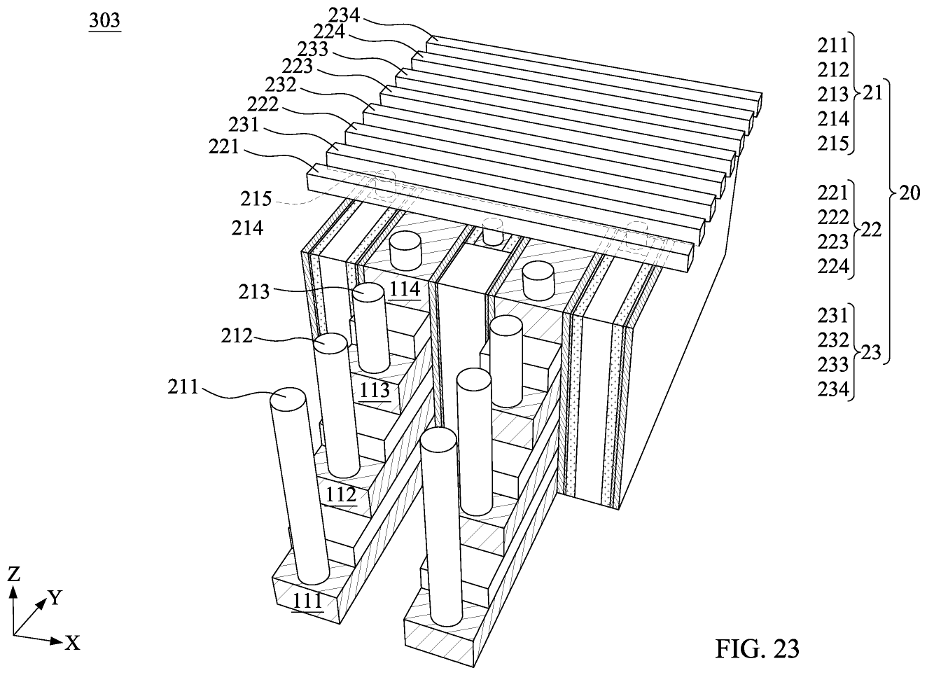

FIG. 23 is a schematic 3D diagram of a semiconductor structure 303 in accordance with some embodiments of the present disclosure. The semiconductor structure 303 is similar to the semiconductor structure 302, but further includes conductive features 20, which include a plurality of contacts 21, a plurality of bit lines 22, and a plurality of source lines 23. In some embodiments, the contacts 21 includes contacts 211, 212, 213 and 214 for electrical connection to the gate layers 111, 112, 113 and 114 respectively. In some embodiments, the contacts 21 also include a contact 215 for electrical connection to the source/drain structures 18. In some embodiments, drain structures (e.g., the drain structures 18b in FIGS. 1 to 6) of the source/drain structures 18 are aligned along the first direction, and all the drain structures are electrically connected to the bit lines 22 (including bit lines 221, 222, 223 and 224). In some embodiments, source structures (e.g., the source structures 18a in FIGS. 1 to 6) of the source/drain structures 18 are aligned along the first direction, and all the source structures are electrically connected to the source lines 23 (including source lines 231, 232, 233 and 234).

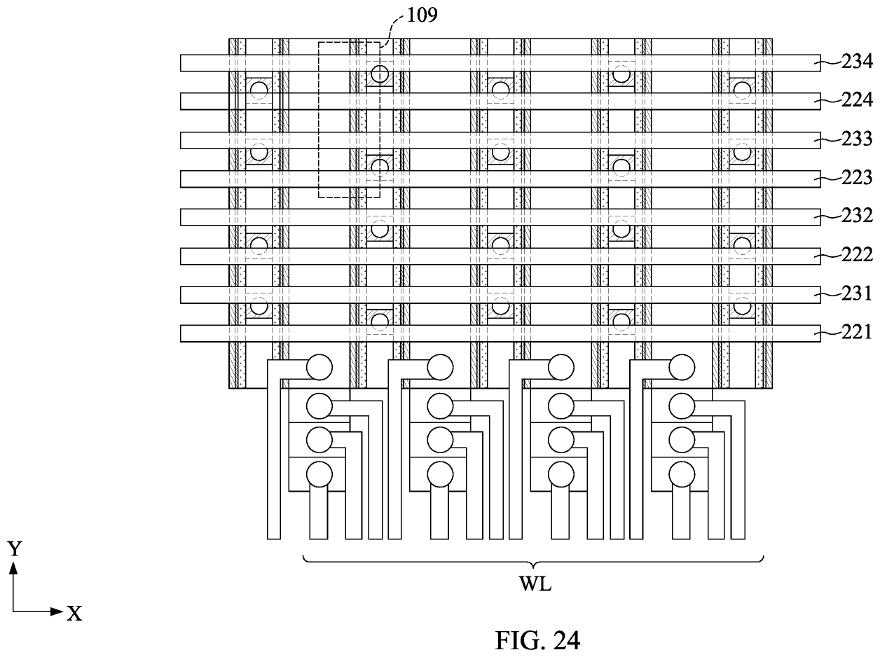

FIG. 24 is a schematic top-view perspective showing electrical connections of the semiconductor structure 303 in accordance with some embodiments of the present disclosure. A plurality of word lines WL electrically connecting the gate layers 11 are shown in FIG. 24 for a purpose of illustration.

To conclude description of the processes of different embodiments as described above, a method 700 is provided.

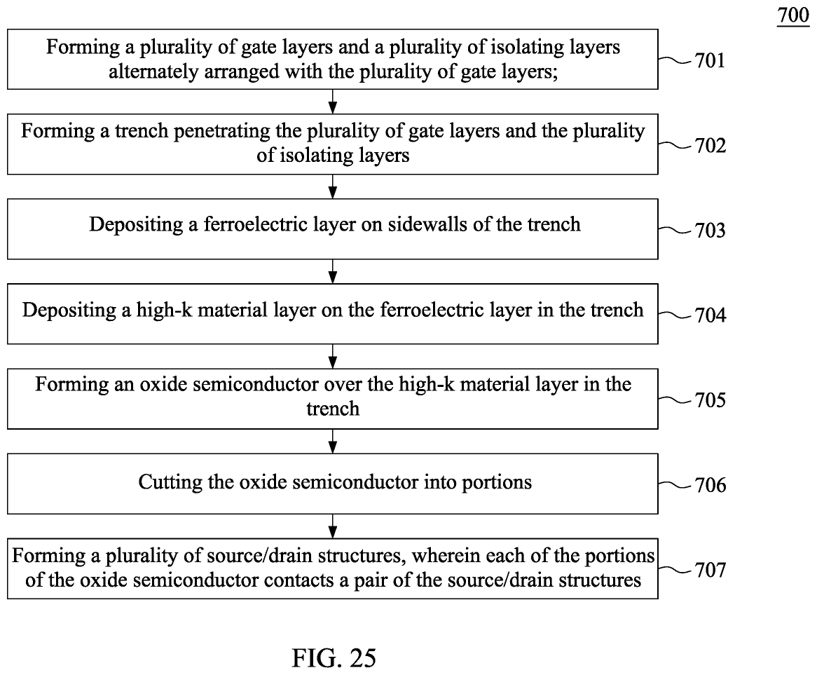

FIG. 25 is a flow diagram of the method 700 for manufacturing a semiconductor structure in accordance with some embodiments of the present disclosure. The method 700 includes a number of operations (701, 702, 703, 704, 705, 706 and 707), and the description and illustration are not deemed as a limitation to the sequence of the operations. In the operation 701, a plurality of gate layers and a plurality of isolating layers alternately arranged with the plurality of gate layers are formed. In the operation 702, a trench penetrating the plurality of gate layers and the plurality of isolating layers is formed. In the operation 703, a ferroelectric layer is deposited on sidewalls of the trench. In the operation 704, a high-k material layer is deposited on the ferroelectric layer in the trench. In the operation 705, an oxide semiconductor is formed over the high-k material layer in the trench. In the operation 706, the oxide semiconductor is cut into portions. In the operation 707, a plurality of source/drain structures are formed, wherein each of the portions of the oxide semiconductor contacts a pair of the source/drain structures.

It should be noted that the operations of the method 700 can be rearranged or otherwise modified within the scope of the various aspects. In some embodiments, additional processes are provided before, during, and after the method 700, and some other processes are only briefly described herein. Thus, other implementations are possible within the scope of the various aspects described herein.

In accordance with some embodiments of the disclosure, a semiconductor structure is provided. The semiconductor structure includes a gate layer, a ferroelectric layer, a source structure, a drain structure, an oxide semiconductor, and a high-k material layer. The gate layer is disposed in an interconnect structure. The ferroelectric layer is disposed over the gate layer. The source structure and the drain structure are disposed over the ferroelectric layer. The oxide semiconductor is disposed over the ferroelectric layer and between the source structure and the drain structure. The high-k material layer is disposed on and contacts a surface of the ferroelectric layer.

In accordance with some embodiments of the disclosure, a semiconductor structure is provided. The semiconductor structure includes a substrate, an interconnect structure, and a ferroelectric memory unit. The substrate includes a logic circuit and a peripheral circuit. The interconnect structure is disposed over the substrate. The ferroelectric memory unit is disposed in the interconnect structure, and comprises: a word line structure, a ferroelectric layer, a bit line structure, a source line structure, an oxide semiconductor and a high-k material layer. The ferroelectric layer is disposed over the word line structure. The bit line structure is disposed over the ferroelectric layer. The source line structure is disposed over the ferroelectric layer and adjacent to the bit line structure. The oxide semiconductor is disposed over the ferroelectric layer and between the bit line structure and the source line structure. The high-k material layer is disposed between the ferroelectric layer and the oxide semiconductor.

In accordance with some embodiments of the disclosure, a method for manufacturing a semiconductor structure is provided. The method may include several operations. A plurality of gate layers and a plurality of isolating layers alternately arranged with the plurality of gate layers are formed. A trench penetrating the plurality of gate layers and the plurality of isolating layers is formed. A ferroelectric layer is deposited on sidewalls of the trench. A high-k material layer is deposited on the ferroelectric layer in the trench. An oxide semiconductor is formed over the high-k material layer in the trench. The oxide semiconductor is cut into portions. A plurality of source/drain structures are formed, wherein each of the portions of the oxide semiconductor contacts a pair of the source/drain structures.

The foregoing outlines features of several embodiments so that those skilled in the art may better understand aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
a gate layer, disposed in an interconnect structure;
a ferroelectric layer, disposed over the gate layer;
a source structure and a drain structure, disposed over the ferroelectric layer;
an oxide semiconductor, disposed over the ferroelectric layer and between the source structure and the drain structure; and
a high-k material layer, disposed on and contacting a surface of the ferroelectric layer.

2. The semiconductor structure of claim 1, wherein the high-k material layer is disposed between the ferroelectric layer and the oxide semiconductor.

3. The semiconductor structure of claim 2, wherein the high-k material layer is entirely between the source structure and the drain structure.

4. The semiconductor structure of claim 2, wherein the high-k material layer is further disposed between the source structure and the ferroelectric layer and between the drain structure and the ferroelectric layer.

5. The semiconductor structure of claim 1, wherein the high-k material layer is disposed between the gate layer and the ferroelectric layer.

6. The semiconductor structure of claim 1, wherein the oxide semiconductor comprises:
a first oxide semiconductor layer, proximal to the ferroelectric layer; and
a second oxide semiconductor layer, disposed on a side of the first oxide semiconductor layer opposite to the ferroelectric layer, wherein a carrier density of the first oxide semiconductor layer is greater than a carrier density of the second oxide semiconductor layer.

7. The semiconductor structure of claim 6, wherein a material of the first oxide semiconductor layer is selected from one or more of a group including gallium oxide (Ga₂O₃), gallium doped zinc oxide (GZO), indium gallium zinc oxide (InGaZnO), indium silicon zinc oxide (InSiZnO), indium zinc tin oxide (InZnSnO), indium tungsten oxide (InWO), and combinations thereof.

8. The semiconductor structure of claim 6, wherein a material of the second oxide semiconductor layer is selected from one or more of a group of zinc oxide (ZnO), indium tungsten oxide (InWO), indium gallium zinc oxide (InGaZnO), indium zinc oxide (InZnO), indium tin oxide (ITO), and combinations thereof.

9. The semiconductor structure of claim 6, wherein a thickness of the first oxide semiconductor layer is in a range of 0.5 to 2 nanometers, and a thickness of the second oxide semiconductor layer is about 3 to 5 times the thickness of the first oxide semiconductor layer.

10. A semiconductor structure, comprising:
a substrate, having a logic circuit and a peripheral circuit;
an interconnect structure, disposed over the substrate; and
a ferroelectric memory unit, disposed in the interconnect structure, the ferroelectric memory unit comprising:
a word line structure;
a ferroelectric layer, disposed over the word line structure;
a bit line structure, disposed over the ferroelectric layer;
a source line structure, disposed over the ferroelectric layer and adjacent to the bit line structure;
an oxide semiconductor, disposed over the ferroelectric layer and between the bit line structure and the source line structure; and
a high-k material layer, disposed between the ferroelectric layer and the oxide semiconductor.

11. The semiconductor structure of claim 10, further comprising:
a capacitor structure, disposed in the interconnect structure and above the ferroelectric memory unit.

12. The semiconductor structure of claim 10, further comprising:
a dielectric layer, surrounding the ferroelectric memory unit, wherein portions of the bit line structure and portions of the source line structure above the oxide semiconductor are separated by the dielectric layer.

13. The semiconductor structure of claim 10, wherein a first portion of the oxide semiconductor is sandwiched between the bit line structure and the high-k material layer, and a second portion of the oxide semiconductor is sandwiched between the source line structure and the high-k material layer.

14. The semiconductor structure of claim 10, wherein the high-k material layer includes aluminum oxide (Al₂O₃), hafnium oxide (HfO₂), zirconium dioxide (ZrO₂), titanium dioxide (TiO₂), niobium monoxide (NbO), lanthanum oxide (La₂O₃), tungsten trioxide (WO₃), molybdenum trioxide (MoO₃), chromium tungsten oxide (CrWOₓ), or a combination thereof.

15. The semiconductor structure of claim 10, wherein a thickness of the high-k material layer is in a range of 0.1 to 2 nanometers.

16. A method of fabricating a semiconductor structure, comprising:
forming a plurality of gate layers and a plurality of isolating layers alternately arranged with the plurality of gate layers;
forming a trench penetrating the plurality of gate layers and the plurality of isolating layers;
depositing a ferroelectric layer on sidewalls of the trench;
depositing a high-k material layer on the ferroelectric layer in the trench;
forming an oxide semiconductor over the high-k material layer in the trench;
cutting the oxide semiconductor into portions; and
forming a plurality of source/drain structures, wherein each of the portions of the oxide semiconductor contacts a pair of the source/drain structures.

17. The method of claim 16, further comprising:
patterning the plurality of gate layers and the plurality of isolating layers, thereby forming a stair configuration of a stacked structure of the plurality of gate layers and the plurality of isolating layers.

18. The method of claim 16, further comprising:
forming a plurality of contacts electrically connecting each of the plurality of gate layers.

19. The method of claim 16, further comprising:
depositing a first dielectric material to fill the trench prior to cutting the oxide semiconductor;
depositing a second dielectric material between the portions of the oxide semiconductor; and
removing portions of the first dielectric material on two opposite sides of the second dielectric material prior to the formation of the plurality of source/drain structures, wherein an etching operation with a higher etch rate selectivity of the first dielectric material with respect to the second dielectric material is performed on the first dielectric material.

20. The method of claim 16, wherein the high-k material layer is in physical contact with the oxide semiconductor and the ferroelectric layer.
